(19) United States
(12) Patent Application Publication
(10) Pub. No.: US 2012/0113593 A1
(43) Pub. Date: May 10, 2012

(54) ELECTRONIC APPARATUS

(75) Inventors: I-Feng HSU, Taipei City (TW); Chang-Yuan WU, Taipei City (TW)

(73) Assignee: COMPAL ELECTRONICS, INC., Taipei City (TW)

(21) Appl. No.: 13/288,967

(22) Filed: Nov. 4, 2011

Related U.S. Application Data
(60) Provisional application No. 61/411,463, filed on Nov. 8, 2010.

(51) Int. Cl. H05K 7/20

(52) U.S. Cl. 361/696; 361/697

(57) ABSTRACT

An electronic apparatus includes a host, a fan module, and a heat-dissipating module. The host includes a first housing, a second housing, and a first housing vent that is located at the edge of the second housing. The fan module includes a fan outlet. The fan module is disposed in the host obliquely, so as to make the fan outlet face the first housing vent. The heat-dissipating module is located between the fan outlet and the first housing vent, and a portion of the first housing vent is located at the bottom of the heat-dissipating module. The airflow generated by the fan module is In exhausted out of the first housing vent via the heat-dissipating module from the fan outlet.

### RELATED APPLICATIONS

This application claims priority to U.S. provisional Application Ser. No. 61/411,463, filed Nov. 8, 2010, which is herein incorporated by reference.

### BACKGROUND

1. Field of Invention

The present invention relates to an electronic apparatus, and more particularly, to an electronic apparatus having a fan module that is disposed obliquely therein.

2. Description of Related Art

Motors are used in a wide range of applications. For example, lathes, drills, saws, etc. used in various kinds of industries include motors, and tape recorders, CD-ROM (compact disc read-only memory) drives, hard drives, pumps, hair dryers, vacuum cleaners, refrigerators, air-conditioning compressors, fans, etc. used in daily life can not operate without motors. In today's information age, the dependence of people on electronic products is increasing. With the ability to offer the features of high-speed, high-performance, and full mobility by today's electronic products, various kinds of portable electronic devices have become ubiquitous. For example, portable electronic devices such as notebook computers, mobile phones, and personal digital assistants have become indispensable application tools of modern life and work.

In order to design a high-performance and compact electronic apparatus, the active cooling components therein must be reduced in size due to the minimal space offered, and still be able to perform the function of exhausting the air in the electronic apparatus to reduce the temperature therein and thus prevent damage to the inner electronic components. Among the active cooling components, fans are applied everywhere. In addition to large equipment for industrial use, many electronic products used in daily life, such as computer power supplies, air conditioners, etc., are equipped with fans to provide a cooling function.

A conventional fan operates by rotating a rotor (i.e., rotation shaft, hub, etc.) relative to a stator, so as to generate airflow that is circulated through an electronic apparatus and subsequently expelled out of the same.

However, if a known fan is used in a thin notebook computer, the housing of the notebook computer that is compressed by an external force and thus deforms will easily contact the rotor of the fan due to the limited space between the housing and the fan. The abrasion between the housing and the fan not only results in the generation of a sharp noise but also in wear of the components of the fan to thereby greatly reduce the lifetime of the fan. Moreover, because the housing and the fan are very close to each other, the air volume exhausted from an outlet of the fan and the amount of air taken in by the fan will be negatively affected, so that the heat-dissipating efficiency is low and difficult to improve.

### SUMMARY

In order to solve the problems of the prior art, the invention provides an improved electronic apparatus. The electronic apparatus of the invention is capable of improving the anti-pressure capacity of the host of the electronic apparatus by obliquely disposing a fan module therein and effectively eliminating noise generated by the fan module when an external force compresses the host. Furthermore, the fan module that is obliquely disposed will increase the air volume during operation, so as to improve the heat-dissipating efficiency of the electronic apparatus. Because the fan module is obliquely disposed in the host, a housing vent can thus be formed at the junction of the bottom and the sidewall of a second housing (i.e., the lower housing of the host) of the host to lower the temperature in the host. Through such a configuration, the electronic apparatus of the invention can achieve a clean-bottom design at the bottom of the second housing.

According to an embodiment of the invention, an electronic apparatus includes a host, a fan module, and a heat-dissipating module. The host includes a first housing and a second housing. The second housing includes a first housing vent that is located at the edge of the second housing. The fan module includes a fan outlet. The fan module is disposed in the host obliquely, so as to make the fan outlet face the first housing vent. The heat-dissipating module includes a heat-dissipating fin assembly and is located between the fan outlet and the first housing vent. A portion of the first housing vent is located at the bottom of the heat-dissipating fin assembly, so that a part of an airflow generated by the fan module is exhausted out of the first housing vent via the heat-dissipating module from the fan outlet.

In an embodiment of the invention, the fan module further includes a fan housing and a rotation shaft that is pivotally connected in the fan housing. The fan outlet is located on the fan housing. An angle formed between the axial direction of the rotation shaft and the normal direction of the second housing is between about 1 and 45 degrees.

In an embodiment of the invention, the fan module further includes a first fastening portion and a second fastening portion respectively disposed at two opposite sides of the fan housing. The fan module is fixed in the host by fastening the first fastening portion to the first housing and fastening the second fastening portion to the second housing.

In an embodiment of the invention, the electronic apparatus further includes a keyboard module disposed at the first housing. The fan module is supported between the first housing and the second housing respectively by the first fastening portion and the second fastening portion when the keyboard module is pressed to deform the first housing toward the second housing.

In an embodiment of the invention, the electronic apparatus further includes a circuit board. The fan module is supported between the first housing and the circuit board respectively by the first fastening portion and the second fastening portion when the first housing is forced to deform toward the second housing.

In an embodiment of the invention, the electronic apparatus further includes a circuit board. The fan module is supported between a circuit board and the second housing respectively by the first fastening portion and the second fastening portion when the first housing is forced to deform toward the second housing.

In an embodiment of the invention, the first housing vent is extended from the sidewall of the second housing to the bottom of the second housing.

In an embodiment of the invention, the electronic apparatus further includes a display module. The display module is pivotally connected to the host and is capable of rotating between a closed position and a largest open position relative to the host, in which the display module and the host are connected by a hidden hinge.

In an embodiment of the invention, the electronic apparatus further includes a heat source. The heat-dissipating module further includes a heat pipe. The heat pipe is thermally connected to the heat source and extends through the heat-dissipating fin assembly for conducting the heat generated by the heat source to the heat-dissipating fin assembly.

In an embodiment of the invention, the electronic apparatus further includes a second housing vent located at the bottom of the second housing and adjacent to the fan outlet. The airflow includes a first branch and a second branch that are exhausted out the host respectively from the first housing vent and the second housing vent.

In an embodiment of the invention, the temperature of the first branch that is exhausted from the first housing vent is higher than that of the second branch that is exhausted from the second housing vent.

In an embodiment of the invention, when the electronic apparatus is placed on a plane, a gap is formed between the electronic apparatus and the plane. The second branch that is exhausted from the second housing vent flows toward the edge of the second housing along the gap, so as to form a low pressure region at the periphery of the second housing vent and thus induce the air in the gap to flow.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a perspective view of an electronic apparatus according to an embodiment of the invention;

FIG. 2A is a sectional view of the electronic apparatus in FIG. 1, in which a display module of the electronic apparatus is at a closed position relative to a host thereof; and

FIG. 2B is a sectional view of the electronic apparatus in FIG. 1, in which the display module is at a largest open position relative to the host.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

An improved electronic apparatus is provided. Specifically, the electronic apparatus of the invention is capable of improving the anti-pressure capacity of the host of the electronic apparatus by obliquely disposing a fan module therein and effectively eliminating noise generated by the fan module when an external force compresses the host. Furthermore, the fan module that is obliquely disposed will increase the air volume during operation, so as to improve the heat-dissipating efficiency of the electronic apparatus. Because the fan module is obliquely disposed in the host, a housing vent can thus be formed at the junction of a bottom and a sidewall of a second housing (i.e., the lower housing of the host) of the host to lower the temperature in the host. Through the above-mentioned configuration, the electronic apparatus of the invention can achieve a clean-bottom design at the bottom of the second housing.

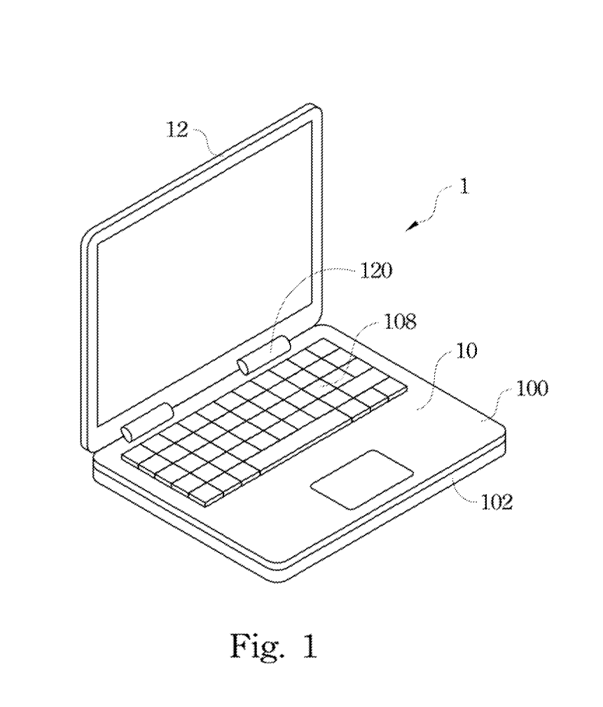

FIG. 1 is a perspective view of an electronic apparatus 1 according to an embodiment of the invention. As shown in FIG. 1, the electronic apparatus 1 of the invention can be a computer device (e.g., a personal computer, a notebook computer, a tablet computer, etc.) or a consumer electronic product (e.g., a projector, a game console, etc.). That is, the electronic apparatus 1 of the invention can be any electronic product having a heat source therein. As long as there is a requirement to dissipate heat, the concepts of the invention can be applied to increase heat-dissipating efficiency during use of a fan module by the electronic apparatus 1 and to effectively prevent generating noise when the electronic apparatus 1 is pressed.

As shown in FIG. 1, a notebook computer is used as an example of the electronic apparatus 1 of the invention. However, the invention is not limited in this regard. The electronic apparatus 1 includes a host 10 and a display module 12. The display module 12 is pivotally connected to the host 10 by a hinge 120. The host 10 of the electronic apparatus 1 includes a first housing 100 and a second housing 102. A keyboard module 108 is disposed at the first housing 100 for user input. The main components of the electronic apparatus 1′ are all disposed in the host 10 (i.e., between the first housing 100 and the second housing 102). The components disposed in the electronic apparatus 1 of the embodiment will be described in detail below. In some cases, the first housing 100 can be the upper housing, and the second housing 102 can be the lower housing.

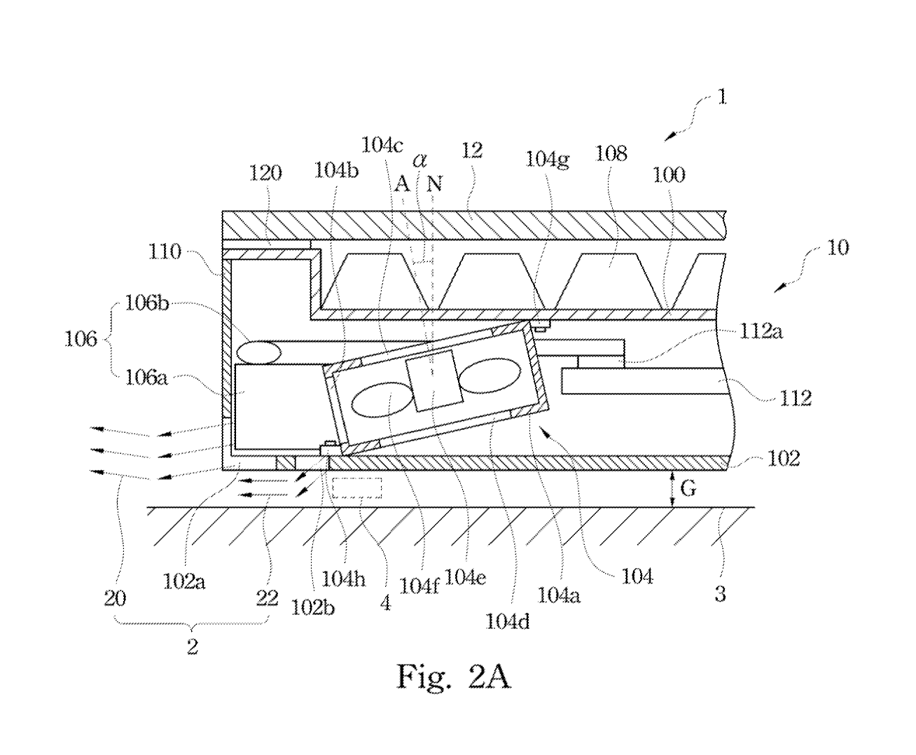

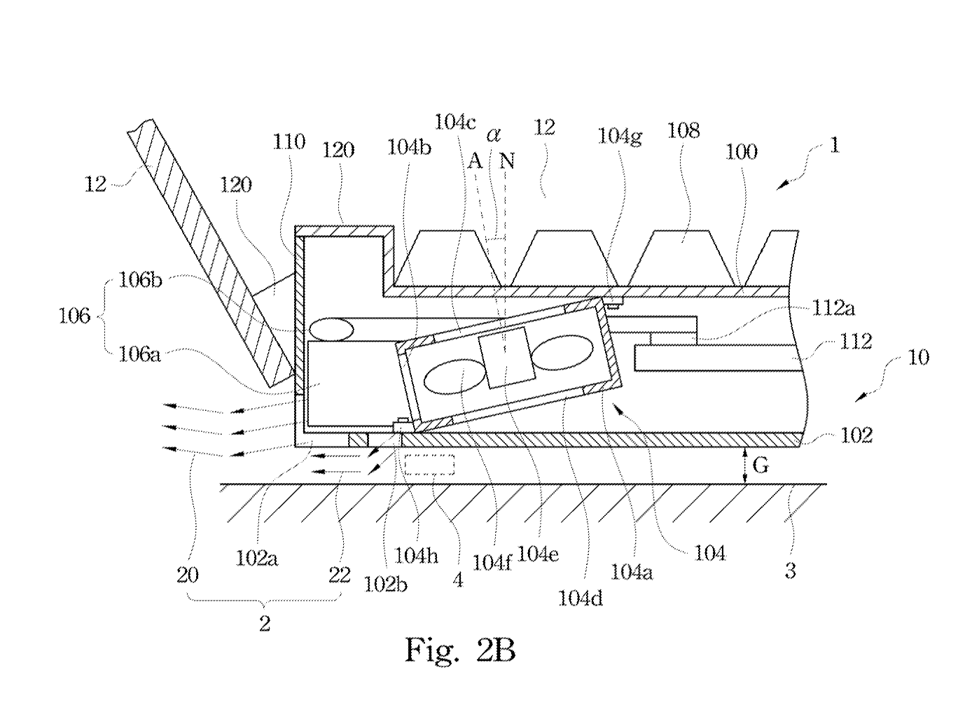

FIG. 2A is a sectional view of the electronic apparatus 1 in FIG. 1, in which the display module 12 is at a closed position relative to the host 10. FIG. 2B is a sectional view of the electronic apparatus 1 in FIG. 1, in which the display module 12 is at a largest open position relative to the host 10.

As shown in FIG. 2A and FIG. 2B, at least one first housing vent 102a is located at the edge of the second housing 102 of the host 10. Further, the first housing vent 102a is extended between a sidewall 110 and a bottom of the second housing 102. In some cases, the first housing vent 102a can be located only at the sidewall 110 of the second housing 102 or can be extended from the sidewall 110 to the bottom of the second housing 102. That is, the first housing vent 102a can be located at the junction of the sidewall 110 and the bottom of the second housing 102. By extending the first housing vent 102a from the sidewall 110 to the bottom of the second housing 102, the exhausting area of the first housing vent 102a can be increased. Moreover, in this case, the display module 12 and the host 10 of the electronic apparatus 1 are pivotally connected to each other by a hidden hinge. Therefore, when the display module 12 of the electronic apparatus 1 rotates from the closed position (as shown in FIG. 2A) to the largest open position (as shown in FIG. 2B) relative to the host 10, the display module 12 will rotate along the sidewall 110 of the second housing 102: Traditionally, a housing vent is usually formed at the sidewall of the host of a conventional electronic apparatus. However, since the electronic apparatus 1 of the invention is thin, and the display module 12 and the host 10 are pivotally connected to each other by the hidden hinge, the display module 12 would overlap a part of the first housing vent 102a if it were formed in the sidewall 110 of the second housing 102. In this case, the heat-dissipating efficiency of the electronic apparatus 1 would be negatively affected when the display module 12 is rotated to the largest open position relative to the host 10. Accordingly, by forming the first housing vent 102a at the junction between the sidewall 110 and the bottom of the second housing 102 to increase the exhausting area, the first housing vent 102a is prevented from being obstructed by the display module 12, such that a high heat-dissipating efficiency of the electronic apparatus 1 is maintained when the display module 12 rotates to the largest open position relative to the host 10.

As shown in FIG. 2A and FIG. 2B, the electronic apparatus 1 further includes a fan module 104 and a circuit board 112. In embodiments where the electronic apparatus 1 is a notebook computer, the circuit board 112 may be a motherboard. The fan module 104 of the electronic apparatus 1 includes a fan outlet 104b. In order to cooperate with the first housing vent 102a located at the bottom of the second housing 102, the fan module 104 must be obliquely disposed in the host 10 of the electronic apparatus 1 with the opposite sides thereof being respectively fixed to the first housing 100 and the second housing 102, so that the fan outlet 104b of the fan module 104 substantially faces (i.e., is better aligned with) the first housing vent 102a located between the sidewall 110 and the bottom of the second housing 102. In some embodiments, the fan module 104 can be fixed between the first housing 100 and the circuit board 112, and in other embodiments, between the circuit board 112 and the second housing 102. Furthermore, the fan module 104 of the electronic apparatus 1 can further include a fan housing 104a, a rotation shaft 104e, and fan blades 104f. The rotation shaft 104e of the fan module 104 is pivotally connected in the fan housing 104a. The fan blades 104f are radially formed around the periphery of the rotation shaft 104e for rotating with the rotation shaft 104e to generate airflow 2. The fan outlet 104b of the fan module 104 is located on the fan housing 104a. Because the fan module 104 is obliquely disposed in the host 10 of the electronic apparatus 1, an angle α will be formed between the axial direction A of the rotation shaft 104e of the fan module 104 and the normal direction N of the second housing 102. In some embodiments, the angle α is between about 1 and 45 degrees. With such a configuration, the second housing 102 of the electronic apparatus 1 does not require an aperture in the projection region of the fan module 104 relative to the second housing 102 along the axial direction A, so as to achieve a clean-bottom design for the second housing 102 of the invention.

As shown in FIG. 2A and FIG. 2B, the fan module 104 can further include a first fastening portion 104g and a second fastening portion 104h. The first fastening portion 104g and the second fastening portion 104h of the fan module 104 are respectively disposed two opposite sides of the fan housing 104a (for example, at diametrically opposed corner regions of the fan housing 104a as shown in FIGS. 2A and 2B). The fan module 104 can be fixed in the host 10 by respectively fastening the first fastening portion 104g and the second fastening portion 104h to the first housing 100 and the second housing 102 with screws or bolts. That is, when the fan module 104 is obliquely disposed in the host 10 of the electronic apparatus 1, the first fastening portion 104g and the second fastening portion 104h are positioned at locations that are respectively adjacent to the first housing 100 and the second housing 102. Therefore, when the fan module 104 is obliquely disposed in the host 10 of the electronic apparatus 1, the fan module 104 is fixed in the host 10 by fastening the first fastening portion 104g to the first housing 100 and fastening the second fastening portion 104h to the second housing 102.

Through use of the foregoing configuration, when the keyboard module 108 of the electronic apparatus 1 is pressed or the first housing 100 is pressed to deform toward the second housing 102, the fan module 104 can be supported between the first housing 100 and the second housing 102 respectively by the first fastening portion 104g and the second fastening portion 104h. In some embodiments, the first fastening portion 104g and the second fastening portion 104h can provide support between the first housing 100 and the circuit board 112, and in other embodiments, between the circuit board 112 and the second housing 102. That is, when the keyboard module 108 of the electronic apparatus 1 is pressed to deform the first housing 100 toward the second housing 102, the deformed first housing 100 will not directly contact the surface of the fan housing 104a of the fan module 104 to result in the fan housing 104a and the fan blades 104f therein to generate unexpected noise. Hence, noise generated by the fan module 104 through such contact is eliminated.

Moreover, the fan housing 104a of the fan module 104 further includes a first fan inlet 104c and a second fan inlet 104d. The first fan inlet 104c and the second fan inlet 104d of the fan housing 104a are respectively adjacent to the first housing 100 and the second housing 102 of the host 10. When the fan blades 104f of the fan module 104 rotate together with the rotation shaft 104e, the air in the host 10 can enter the fan module 104 via the first fan inlet 104c and the second fan inlet 104d. Because the fan module 104 is obliquely disposed in the host 10, the distance between the first fan inlet 104c and the first housing 100 and that between the second fan inlet 104d and the second housing 102 can be increased, so as to achieve the purpose of increasing the air-intake volume of the fan module 104.

As shown in FIG. 2A and FIG. 2B, the electronic apparatus 1 further includes a heat-dissipating module 106. The circuit board 112 is fixed in the host 10 and includes at least one heat source 112a. The heat-dissipating module 106 of the electronic apparatus 1 is disposed in the host 10 and located between the fan outlet 104b of the fan module 104 and the first housing vent 102a. The airflow 2 generated by the fan module 104 is exhausted out of the first housing vent 102a from the fan outlet 104b via the heat-dissipating module 106. The heat-dissipating module 106 of the electronic apparatus 1 includes a heat-dissipating fin assembly 106a and a heat pipe 106b. The heat-dissipating fin assembly 106a of the heat-dissipating module 106 is located between the fan outlet 104b of the fan module 104 and the first housing vent 102a. The airflow 2 is exhausted out of the first housing vent 102a from the fan outlet 104b via the heat-dissipating fin assembly 106a. The heat pipe 106b of the heat-dissipating module 106 is thermally connected to the heat source 112a of the circuit board 112 and extends through the heat-dissipating fin assembly 106a, so that the heat generated by the heat source 112a can be conducted to the heat-dissipating fin assembly 106a and be dissipated by the airflow 2. In some embodiments, a portion of the first housing vent 102a located at the bottom of the second housing 102 is located under the heat-dissipating fin assembly 106a. Stated differently, this portion of the first housing vent 102a is located under the heat-dissipating module 106.

Moreover, because the fan module 104 is obliquely disposed in the host 10 and the heat pipe 106b extends through the heat-dissipating fin assembly 106a near the top of the heat-dissipating fin assembly 106a, the heat pipe 106b of the heat-dissipating module 106 is deviated from the fan outlet 104b of the fan module 104. That is, the heat pipe 106b of the heat-dissipating module 106 does not face the fan outlet 104b of the fan module 104 (i.e., is not horizontally aligned with the fan outlet 104b of the fan module 104). Therefore, during the process in which the airflow 2 exhausted from the fan outlet 104b of the fan module 104 passes through the heat-dissipating fin assembly 106a and then is exhausted out of the first housing vent 102a, the airflow 2 will not be obstructed by the heat pipe 106b, thereby decreasing the flow resistance between the fan outlet 104b of the fan module 104 and the first housing vent 102a.

As shown in FIG. 2A and FIG. 2B, the electronic apparatus 1 of the embodiment further includes at least one second housing vent 102b. The second housing vent 102b is located at the bottom of the second housing 102 and adjacent to the fan outlet 104b of the fan module 104. Even though the second housing vent 102b is located at the bottom of the second housing 102, a part of the airflow 2 generated by the fan module 104 will still be exhausted out from the second housing vent 102b because the fan module 104 is obliquely disposed in the host 10. That is, the airflow 2 generated by the fan module 104 includes a first branch 20 and a second branch 22 that are exhausted out the host 10 respectively from the first housing vent 102a and the second housing vent 102b. Because the first branch 20 passes through the heat-dissipating module 106 and then is exhausted out of the first housing vent 102a whereas the second branch 22 is exhausted from the fan outlet 104b and exhausted out of the second housing vent 102b without passing through the heat-dissipating module 106, the temperature of the second branch 22 is lower than that of the first branch 20. In this case, the second housing vent 102b is distanced farther away from the sidewall 110 of the electronic apparatus 1 than the first housing vent 102a is. When the electronic apparatus 1 is placed on a plane 3, a gap G is formed between the electronic apparatus 1 and the plane 3. As an example, the gap G may be formed through integrally formed legs (not shown) on the bottom of the second housing 102. Therefore, the second branch 22 that is exhausted from the second housing vent 102b flows toward the edge of the second housing 102 along the gap G between the bottom of the second housing 102 and the plane 3, so as to form a low pressure region 4 adjacent to the second housing vent 102b (particularly, adjacent to the second housing vent 102b at an area away from the sidewall 110) and thus induce the air in the gap G to flow. Accordingly, when the electronic apparatus 1 is placed on a plane 3, the low pressure generated by the second branch 22 at the low pressure region 4 is capable of effectively dissipating the heat under the second housing 102 by attracting air from the area around the electronic apparatus with a lower temperature to the bottom of the second housing 102. Hence, such a configuration and operation provide an improvement to the problem associated with difficult circulation of air between the second housing 102 of the electronic apparatus 1 and the plane 3.

According to the foregoing recitations of the embodiments of the invention, it can be seen that the electronic apparatus of the invention is capable of improving the anti-pressure capacity of the host of the electronic apparatus by obliquely disposing a fan module therein and effectively eliminating noise generated by the fan module when the host is compressed by an external force. Furthermore, the fan module that is obliquely disposed will increase the air volume during operation, so as to improve the heat-dissipating efficiency of the electronic apparatus. Because the fan module is obliquely disposed in the host, a housing vent can thus be formed at the junction of the bottom and the sidewall of a second housing (i.e., the lower housing of the host) of the host to lower the temperature in the host. Through such a configuration, the electronic apparatus of the invention can achieve a clean-bottom design at the bottom of the second housing.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An electronic apparatus comprising:
a host comprising a first housing and a second housing, wherein the second housing comprises a first housing vent that is located at the edge of the second housing;
a fan module comprising a fan outlet, wherein the fan module is disposed in the host obliquely, so as to make the fan outlet face the first housing vent; and
a heat-dissipating module disposed between the fan outlet and the first housing vent, and comprising a heat-dissipating fin assembly, wherein a portion of the first housing vent is located at the bottom of the heat-dissipating fin assembly, so that a part of an airflow generated by the fan module is exhausted out of the first housing vent via the heat-dissipating module from the fan outlet.

2. The electronic apparatus of claim 1, wherein the fan module further comprises a fan housing and a rotation shaft that is pivotally connected in the fan housing, the fan outlet is located on the fan housing, and an angle formed between the axial direction of the rotation shaft and the normal direction of the second housing is between about 1 and 45 degrees.

3. The electronic apparatus of claim 2, wherein the fan module further comprises a first fastening portion and a second fastening portion respectively disposed at two opposite sides of the fan housing, and the fan module is fixed in the host by fastening the first fastening portion to the first housing and fastening the second fastening portion to the second housing.

4. The electronic apparatus of claim 3, further comprising a keyboard module disposed at the first housing, wherein the fan module is supported between the first housing and the second housing respectively by the first fastening portion and the second fastening portion when the keyboard module is pressed to deform the first housing toward the second housing.

5. The electronic apparatus of claim 3, further comprising a circuit board, wherein the fan module is supported between the first housing and the circuit board respectively by the first fastening portion and the second fastening portion when the first housing is forced to deform toward the second housing.

6. The electronic apparatus of claim 3, further comprising a circuit board, wherein the fan module is supported between the circuit board and the second housing respectively by the first fastening portion and the second fastening portion when the first housing is forced to deform toward the second housing.

7. The electronic apparatus of claim 1, wherein the first housing vent is extended from the sidewall of the second housing to the bottom of the second housing.

8. The electronic apparatus of claim 7, further comprising a display module pivotally connected to the host and capable of rotating between a closed position and a largest open position relative to the host, wherein the display module and the host are connected by a hidden hinge.

9. The electronic apparatus of claim 1, further comprising a heat source, the heat-dissipating module further comprising:
a heat pipe being thermally connected to the heat source and extending through the heat-dissipating fin assembly for conducting the heat generated by the heat source to the heat-dissipating fin assembly.

10. The electronic apparatus of claim 1, further comprising a second housing vent located at the bottom of the second housing and adjacent to the fan outlet, wherein the airflow comprises a first branch and a second branch that are exhausted out the host respectively from the first housing vent and the second housing vent.

11. The electronic apparatus of claim 10, wherein the temperature of the first branch that is exhausted from the first housing vent is higher than that of the second branch that is exhausted from the second housing vent.

12. The electronic apparatus of claim 10, wherein when the electronic apparatus is placed on a plane, a gap is formed between the electronic apparatus and the plane, and wherein the second branch that is exhausted from the second housing vent flows toward the edge of the second housing along the gap, so as to form a low pressure region at the periphery of the second housing vent and thus induce the air in the gap to flow.
